(19) United States
(12) Patent Application Publication
(10) Pub. No.: US 2009/0189145 A1
(43) Pub. Date: Jul. 30, 2009

(54) Photodetectors, Photovoltaic Devices And Methods Of Making The Same

(76) Inventors: Shih-Yuan Wang, Palo Alto, CA (US); Nobuhiko Kobayashi, Sunnyvale, CA (US); Michael Tan, Menlo Park, CA (US); R. Stanley Williams, Portola Valley, CA (US); Denny Houng, Cupertino, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/253,152

(22) Filed: Oct. 16, 2008

Related U.S. Application Data
(60) Provisional application No. 61/024,754, filed on Jan. 30, 2008.

(51) Int. Cl. H01L 31/00; H01L 21/20

(52) U.S. Cl. 257/14; 438/478; 977/762; 438/57; 438/681; 257/E21.09; 257/E31.002

(57) ABSTRACT

A photodetector includes a first layer, a second layer and a plurality of nanowires established between the first and second layers. At least some of the plurality of nanowires have a bandgap that is different from a bandgap of at least some other of the plurality of nanowires.

### CROSS-REFERENCE TO RELATED APPLICATION

The present application claims priority from provisional application Ser. No. 61/024,754, filed Jan. 30, 2008, the contents of which are incorporated herein by reference in their entirety.

### BACKGROUND

The present disclosure relates generally to photodetectors, photovoltaic devices, and methods of making the same.

Since the inception of semiconductor technology, a consistent trend has been toward the development of smaller device dimensions and higher device densities. As a result, nanotechnology has seen explosive growth and generated considerable interest. Nanotechnology is centered on the fabrication and application of nano-scale structures, or structures having dimensions that are often 5 to 100 times smaller than conventional semiconductor structures. Nanowires are included in the category of nano-scale structures.

Nanowires are wire-like structures having at least one linear dimension (e.g., diameter) ranging from about 1 nm to about 800 nm. It is to be understood that the diameter of the nanowire may also vary along the length (e.g., from several hundred nanometers at the base to a few nanometers at the tip). Nanowires are suitable for use in a variety of applications, including functioning as conventional wires for interconnection applications or as semiconductor devices. Nanowires are also the building blocks of many potential nano-scale devices, such as photodetectors, nano-scale field effect transistors (FETs), p-n diodes, light emitting diodes (LEDs), lasers, and nanowire-based sensors, to name a few.

### BRIEF DESCRIPTION OF THE DRAWINGS

Features and advantages of embodiments of the present disclosure will become apparent by reference to the following detailed description and drawings, in which like reference numerals correspond to the same or similar, though perhaps not identical, components. For the sake of brevity, reference numerals having a previously described function may or may not be described in connection with subsequent drawings in which they appear.

FIG. 1 is a schematic view of an embodiment of a photodetector having substantially vertical nanowires established between two layers;

FIG. 2 is a schematic view of an embodiment of a photodetector having substantially horizontal nanowires established between two layers;

FIG. 3 is a schematic view of another embodiment of a photodetector having substantially horizontal nanowires established between two layers;

FIG. 4 is a schematic view of still another embodiment of a photodetector having substantially horizontal nanowires established between various sub-layers of two layers; and

FIG. 5 is a schematic view of an embodiment of a photovoltaic device.

### DETAILED DESCRIPTION

Embodiments of the photodetectors and photovoltaic devices disclosed herein advantageously include multiple nanowires having different bandgaps. Including nanowires with different bandgaps advantageously broadens the absorption spectrum for the photodetector or photovoltaic device, thereby increasing its efficiency.

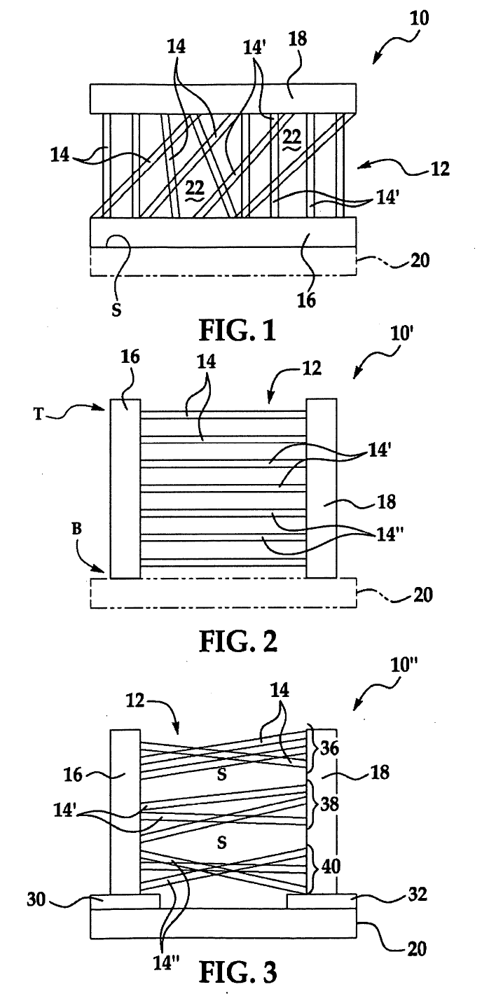

Referring now to FIG. 1, an embodiment of the photodetector 10 is depicted. In this embodiment, a plurality 12 of nanowires 14, 14′ is established between a first layer 16 and a second layer 18.

It is to be understood that one of the layers 16, 18 positioned at an end of the photodetector 10 may function as a substrate for the photodetector 10. In such embodiments, the layer 16, 18 functioning as the substrate generally has a thickness that is greater than the other layer 18, 16.

In other embodiments, one of the layers 16, 18 may be established on a separate substrate 20. Non-limiting examples of suitable substrate materials include amorphous materials, polycrystalline materials, or single crystalline materials. More specifically, the substrate 20 may be a conducting material (e.g., metal), a semiconductor material (e.g., silicon), or an insulator material (e.g. glass, SiO₂). The substrate 20 may also include an insulating layer (not shown) established between conducting portions of the substrate 20 or at a surface of the substrate 20. It is to be understood that unless it is desirable to illuminate the photodetector 10 through the substrate 20, the substrate 20 may not be transparent to one or more wavelengths/range of wavelengths of interest. The substrate 20 may be one or more hundreds of microns thick, and in one embodiment, the thickness of the substrate 20 ranges from about 25 microns to about 1000 microns.

If an additional substrate 20 is used, the desirable layer 16, 18 may be established on the substrate 20 via any suitable deposition technique. Non-limiting examples of such techniques include plasma enhanced chemical vapor deposition (PECVD), thermal evaporation, chemical vapor deposition (CVD), sputtering, or the like.

Generally, materials suitable for forming the layers 16, 18 may be amorphous, polycrystalline, single crystalline, or a hybrid of such materials. A non-limiting example of a hybrid material includes a conductive material core (e.g., stainless steel) coated with a layer of a doped material (e.g., p-type or n-type microcrystalline silicon). Furthermore, the layers 16, 18 of the photodetector 10 may be formed of semiconductor materials (e.g., silicon, germanium, gallium nitride, gallium phosphide, or the like) or conducting materials (e.g., metals, indium tin oxide, stainless steel, or the like). As such, the layers 16, 18 may be electrodes. In some instances, the layers 16, 18 also have different conductivity types. For example, the first layer 16 may be doped to exhibit n-type or p-type conductivity, and the second layer 18 may be doped to exhibit the other of p-type or n-type conductivity. In other instances, the layers 16, 18 have the same conductivity types. This may be particularly suitable when junctions (e.g., p-i-n junctions) are formed in the nanowires 14, 14′, and the p-type and n-type segments of the nanowires 14, 14′ connect to the conductive surfaces of the layers 16, 18.

The layer 16 generally has a thickness ranging from about 10 nm to about 1000 nm, and the layer 18 has a thickness ranging from about 10 nm to about 3100 nm. In some instances, the layer 18 is made up of two or more layers of different materials. As a non-limiting example, the layer 18 may include a first layer (e.g., a transparent n-type or p-type doped microcrystalline or amorphous silicon) having a thickness ranging from about 10 nm to about 100 nm and a second layer (e.g., a conductive transparent oxide, such as indium tin oxide (ITO)) ranging from about 10 nm to about 3000 nm.

The layers 16, 18 may also be substantially transparent. As used herein, the phrase “substantially transparent” means that the material selected for the layers 16, 18 allows light of a predetermined wavelength or range of wavelengths to pass therethrough. It is to be understood that any layer 16, 18 functioning as the substrate or established on the substrate 20 may not be substantially transparent, unless it is desirable to illuminate the photodetector 10 through that particular layer 16, 18 and/or substrate 20. In an embodiment, the layers 16, 18 are substantially transparent to at least the wavelength/range of wavelengths that is to be absorbed by the nanowires 14, 14′. A non-limiting example of a substantially transparent layer 16, 18 includes a thin layer (e.g., about 20 nm to about 100 nm) of microcrystalline or amorphous silicon on an ITO core.

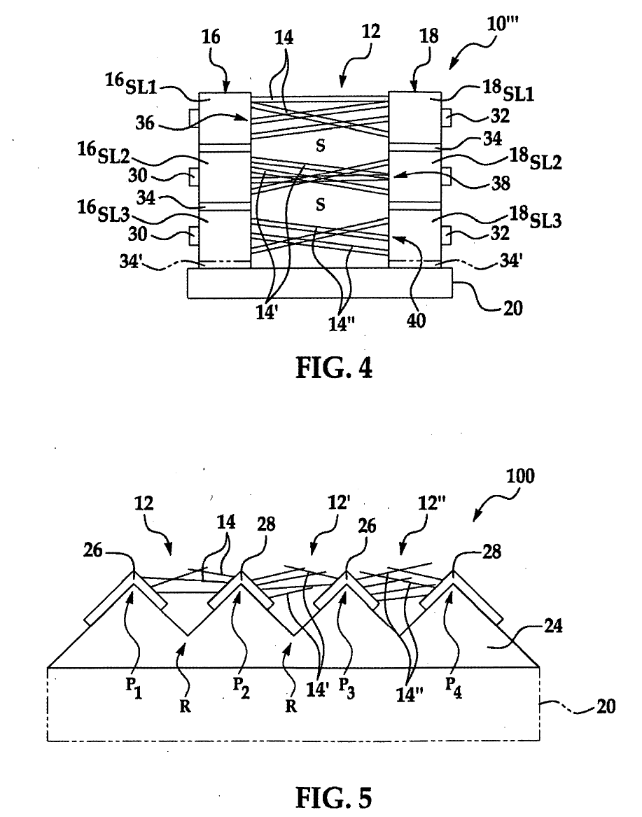

As previously mentioned, the plurality 12 of nanowires 14, 14′ extends between the first and second layers 16, 18. It is to be understood that the nanowires 14, 14′ may be intermingled (as shown in FIG. 1) or may be separated (as shown and discussed further in reference to FIGS. 3 and 4).

In the embodiment shown in FIG. 1, the nanowires 14, 14′ are substantially vertically oriented between the layers 16, 18. The terms “substantially vertically” and “substantially vertical” as they are used herein mean that the nanowires 14, 14′ may be vertically oriented (with respect to a surface of the layer 16, 18 from which they are grown), oriented at any non-zero angle from the vertical, or combinations thereof. In some instances, the nanowires 14, 14′ are randomly oriented (i.e., the plurality 12 includes a variety of non-vertical angled nanowires 14, 14′ or a combination of vertical and non-vertical angled nanowires 14, 14′).

Generally, the orientation of the nanowires 14, 14′ depends, at least in part, on the crystallography of the layer 16, 18 from which the nanowires 14, 14′ are grown. For example, nanowires 14, 14′ having a particular direction (e.g., vertical nanowires) are grown from a single crystalline layer. The formation of nanowires 14, 14′ at non-zero angles from the vertical may be achieved by selecting the layer 16, 18 having a suitable crystallographic orientation for forming such angled nanowires 14, 14′. Still further, when an amorphous or microcrystalline layer (e.g., amorphous or microcrystalline silicon, germanium, etc.) 16, 18 is used, there is no single orientation and so the growing nanowires 14, 14′ are randomly aligned. Such a random orientation may be desirable, at least in part, because such nanowires 14, 14′ are able to capture light efficiently from a variety of angles and polarization.

The plurality 12 of nanowires 14, 14′ in the embodiment of FIG. 1 include some nanowires 14 which have a bandgap that is different from a bandgap of other nanowires 14′. In such embodiments, the nanowires 14 are capable of absorbing light of a first wavelength or range of wavelengths, and the nanowires 14′ are capable of absorbing light of a second wavelength or range of wavelengths that is different from the first wavelength or range of wavelengths.

In an embodiment, the nanowires 14, 14′ having different bandgaps are formed of different semiconductor materials. Such semiconductor materials may be selected from silicon, germanium, indium phosphide, gallium arsenide, gallium nitride, indium antimonide, indium nitride, indium gallium nitride, or combinations thereof. In some instances, the nanowires 14, 14′ are formed of undoped intrinsic materials. In other instances, the nanowires 14, 14′ may be exposed to one or more dopants (during growth) that is/are capable of introducing different conductivity types to one or more segments of the nanowire(s) 14, 14′.

Generally, the dopant is introduced with a precursor gas used to grow the nanowires 14, 14′ (described further hereinbelow). In some instances, the nanowires 14, 14′ are formed with segments that are doped differently, such that p-n junctions are formed along the length of the nanowires 14, 14′. For example, one of the segments is doped p-type or n-type and the other of the segments is doped the other of n-type or p-type. When the nanowires 14, 14′ are doped to have segments with different conductivity types along their length, junctions (not shown) are axially formed in the nanowire 14, 14′ at the interface of the two differently doped segments.

The nanowires 14, 14′ may also be grown and doped to include multiple p-type and n-type segments, or to include an undoped or lightly doped (compared to the other doped segments) semiconductor region between two doped regions, the latter of which forms a p-i-n structure. Dopants for introducing p-type conductivity into group IV semiconductors include, but are not limited to boron, other like elements, or combinations thereof; and dopants for introducing n-type conductivity into group IV semiconductors include, but are not limited to phosphorus, arsenic, antimony, other like elements, or combinations thereof. Different dopants may be suitable for group III-V materials, such as, for example silicon, carbon, zinc, or the like, or combinations thereof.

In one non-limiting example, some of the nanowires 14 are formed of gallium nitride and others of the nanowires 14′ are formed of indium nitride and alloys of indium gallium nitride and aluminum gallium nitride. While the plurality 12 shown in FIG. 1 includes nanowires 14, 14′ having two different bandgaps, it is to be understood that any number of different types of nanowires 14, 14′ may be included in the plurality 12.

In another embodiment, the nanowires 14, 14′ having different bandgaps have different diameters. It is to be understood that the diameters of the nanowires 14, 14′ may be varied by using catalyst nanoparticles of different sizes. The nanowire 14, 14′ diameter may also be varied by oxidizing the outer surfaces of at least some of the nanowire 14, 14′. As a non-limiting example, the outer surfaces of silicon nanowires 14, 14′ may be oxidized to form SiO₂, thereby reducing the diameter of the nanowire 14, 14′. As another non-limiting example, the aluminum of AlGaAs nanowires 14, 14′ may be oxidized to form Al₂O₃, thereby reducing the diameter of the nanowire 14, 14′. Still another suitable method for forming nanowires 14, 14′ with different diameters includes etching back at least some of the nanowires 14, 14′ using, for example, PECVD. Nanowires 14, 14′ having a diameter of less than about 60 nm tend exhibit larger bandgaps. As such, in a non-limiting example, some of the nanowires 14 may have a diameter less than 60 nm, and others of the nanowires 14′ may have a diameter greater than 60 nm.

It is to be further understood that the nanowires 14, 14′ are established such that an electrical connection is made at the terminal ends of each of the nanowires 14, 14′. In the embodiment shown in FIG. 1, the nanowires 14, 14′ are generally grown from the layer 16, 18 and are connected/attached to the other layer 18, 16. Growth may be accomplished using catalyst nanoparticles and precursor gases.

Forming the plurality 12 of nanowires 14, 14′ may include establishing a first plurality of catalyst nanoparticles on the first layer 16. In one embodiment, the catalyst nanoparticles may be formed by depositing (on the first layer 16) material(s) that subsequently form the catalyst nanoparticle (e.g., upon exposure to heating). In another embodiment, pre-formed catalyst nanoparticles may be deposited on the first layer 16. In either embodiment, suitable deposition processes include, but are not limited to physical deposition processes, solution deposition processes, chemical vapor deposition processes, electrochemical deposition processes, and/or combinations thereof. Non-limiting examples of suitable catalyst nanoparticle materials include gold, titanium, platinum, palladium, gallium, nickel, or combinations thereof.

Growth of some of the nanowires 14 may be initiated via selective exposure of the first plurality of catalyst nanoparticles to a precursor gas. When using catalyst nanoparticles, it is to be understood that the material that forms the nanowires 14 is supplied, for example, in the form of the gaseous precursor containing one or more components of material that form the nanowires 14. As such, the precursor gas is selected so that nanowires 14 of a desirable material are formed. Metal organic chemical vapor deposition (MOCVD), gas source molecular beam epitaxy (MBE), hydride vapor phase epitaxy (HVPE), or chloride vapor phase epitaxy (Cl-VPE) may be used to expose the nanoparticles to the precursor gas.

It is to be understood that HPVE and Cl-VPE may be particularly suitable for relatively high volume production of the nanowires 14, 14′. As non-limiting examples, HVPE may have a growth rate of about 100 μm/hr, and VPE may have a growth rate as high as 300 μm/hour. HVPE and Cl-VPE are similar, and the growth conditions are near equilibrium; as such, the growth rate is determined by the mass input rates of the reactants. In MOCVD, the growth process is far from equilibrium and the growth rate is determined by surface kinetics, which may be desirable in some instances.

Once some of the nanowires 14 are formed, a second plurality of catalyst nanoparticles is established on the first layer 16. The second plurality of catalyst nanoparticles is then exposed to another precursor gas (e.g., via MOCVD), thereby initiating growth of the other nanowires 14′. Since it is desirable that the bandgaps of the respective nanowires 14, 14′ be different, it may also desirable that the precursor gases used to form the respective nanowires 14, 14′ be different or that the diameters of the respective nanowires 14, 14′ be different. As described herein, generally the nanowires 14, 14′ are grown sequentially.

In some instances, the catalyst nanoparticles used to grow the nanowires 14 may be removed prior to growth of the nanowires 14′. This may be accomplished to ensure that the nanowires 14 do not continue to grow during growth of the nanowires 14′. Selective etching processes may be used to remove the catalyst nanoparticles.

When intermingled nanowires 14, 14′ are desired, a single layer of catalyst nanoparticles may be deposited on the layer 16, and then some of the catalyst nanoparticles may selectively exposed to a first precursor gas to initiate growth of some of the nanowires 14. Once these nanowires 14 are grown, the remainder of the catalyst nanoparticles may be selectively exposed to a second precursor gas to initiate growth of the other nanowires 14′. Such selective exposure may be accomplished, for example, using a mask layer.

After the plurality 12 of nanowires 14, 14′ is grown, a layer 22 may be formed on the first layer 16 such that it surrounds each of the nanowires 14, 14′. As such, layer 22 substantially fills the spaces between respective nanowires 14, 14′. Such a layer 22 may be grown or deposited. Non-limiting examples of materials suitable for the layer 22 include substantially transparent insulating materials (e.g., silicon dioxide, silicon nitride, polyimide, spin-on-glass, or the like). Such materials are generally transparent to the wavelength/range of wavelengths of interest that are to be absorbed by the respective nanowires 14, 14′. The layer 22 may be established such that it covers any exposed terminal ends of the nanowires 14, 14′. The layer 22 and the nanowires 14, 14′ may then be exposed to planarization (e.g., chemical mechanical planarization) to form a substantially planar surface in which the previously exposed terminal end of each of the nanowires 14, 14′ is re-exposed. The second layer 18 is then established on this planar surface such that an electrical connection is formed between the nanowires 14, 14′ and the second layer 18. The second layer 18 may be deposited via any suitable method, including, but not limited to PECVD (e.g., for microcrystalline or amorphous materials, or conductive oxides (ITO)), thermal evaporation (e.g., for conductive oxides) or sputtering (e.g., for conductive oxides).

In a non-limiting example, the photodetector 10 includes the first layer 16 formed of micro-crystalline silicon having n-type conductivity and the second layer 18 formed of a layer of micro-crystalline silicon having p-type conductivity and a layer of ITO to reduce the series resistance. The nanowires 14, 14′ are formed of different intrinsic semiconductor materials, some of which have a first bandgap and others of which have a second bandgap. Such a photodetector 10 is a p-i-n structure and a photovoltaic cell that is capable of converting light of different wavelengths/range of wavelengths into electricity. In use, light beams are directed into the photodetector 10. Those light beams having a wavelength or range of wavelengths that correspond to a particular nanowire 14, 14′ are absorbed by the nanowire 14, 14′, and are converted into electricity.

It is to be understood that a junction (not shown) for light absorption may be desirably positioned within the device 10. It is to be understood that in instances when all of the layers 16, 18 and nanowires 14, 14′ are formed with the same conductivity type or the same type and level of conductivity, no junction is formed in the device 10, and the device 10 is suitable for operating in photoconductive mode. When a junction is desirable, it is formed where two materials having differing conductivity types and/or different conductivity levels (e.g., n-n⁺, where “n⁺” indicates a higher level of doping than n alone) meet. More specifically, the junction may be formed i) along the length of any of the nanowires 14, 14′ (described hereinabove) and/or ii) at an interface between the nanowires 14, 14′ and a respective one of the layers 16, 18. It is to be understood that when included, the junction may be positioned to achieve desirable absorption.

In embodiments in which both layers 16, 18 are established on the substrate 20 (see FIGS. 2, 3 and 4), it is to be understood that the layers 16, 18 may be formed of the same material as the substrate 20, if the substrate 20 is non-conductive and microcrystalline silicon (or another like material) is deposited on each layer 16, 18, for example, by PECVD. If, however, the substrate 20 is conductive, one of the layers 16, 18 may be formed of the same material as the substrate 20, while the other layer 18, 16 may include an insulator established between that layer 18, 16 and the substrate 20. In such an embodiment, a separate electrode is connected to the other layer 18, 16. Still other embodiments of the devices 10′, 10″, 10′″ including both layers 16, 18 established on the substrate 20 are shown and described in FIGS. 2, 3 and 4, respectively.

Referring now to FIG. 2, another embodiment of a photodetector 10′ is depicted. In this embodiment, there are three types of nanowires 14, 14′, 14″ formed between the layers 16, 18, each of which has a different bandgap (formed by varying the composition or by varying the diameter of the nanowires 14, 14′, 14″). It is to be understood that the materials and processes described above in reference to FIG. 1 may be used to form the embodiment shown in FIG. 2.

The plurality 12 of nanowires 14, 14′, 14″ shown in FIG. 2 is substantially horizontally oriented between the layers 16, 18. The terms “substantially horizontally” and “substantially horizontal” as they are used herein mean that the nanowires 14, 14′, 14″ horizontally oriented with respect to a surface of the layer 16, 18 (e.g., oriented 90′ with respect to a vertical surface of the layer 16, 18), oriented at any non-zero angle from the horizontal, or combinations thereof. In some instances, the nanowires 14, 14′, 14″ are randomly oriented (i.e., the plurality 12 includes a variety of non-horizontal angled nanowires 14, 14′ or horizontal and non-horizontal angled nanowires 14, 14′, 14″). The terms “substantially horizontally” and “substantially horizontal” may also include embodiments in which the nanowires 14, 14′, 14″ extend from one surface horizontally or at any non-zero angle from the horizontal, and do not attach to another surface (see, for example, FIG. 5).

As previously mentioned, the embodiment shown in FIG. 2 includes each of the nanowires 14, 14′, 14″ oriented horizontally with respect to the surface from which it is grown. It is to be understood that the layer 16, 18 from which such nanowires 14, 14′, 14″ are grown is a single crystalline material having a suitable crystallographic orientation at the surface for growing such horizontal nanowires 14, 14′, 14″. The embodiment of FIG. 2 may include (instead of horizontal nanowires 14, 14′, 14″) randomly oriented nanowires 14, 14′, 14″ that are grown from a non-single crystalline, microcrystalline or amorphous material layer 16, 18.

In this embodiment, nanowires 14 have a different bandgap than nanowires 14′, and nanowires 14″ have a different bandgap than the bandgaps of both nanowires 14, 14′. As a non-limiting example, the nanowires 14 positioned near a top T of the photodetector 10′ have a bandgap suitable for absorbing shorter wavelengths than nanowires 14′, and the nanowires 14″ positioned near a bottom B of the photodetector 10′ have a bandgap suitable for absorbing longer wavelengths than nanowires 14′. In this non-limiting example, the nanowires 14 may be formed of gallium nitride, the nanowires 14′ may be formed of gallium arsenide or indium gallium nitride, and the nanowires 14″ may be formed of indium antimonide or indium nitride. It is to be understood, however, that the nanowires 14, 14′, 14″ may be positioned such that those capable of absorbing the longest wavelengths are located near the top T of the photodetector 10′ and those capable of absorbing the shortest wavelengths are located near the bottom B. This embodiment may be particularly suitable when the device 10′ is illuminated from the bottom B (where the substrate 20 is substantially transparent (e.g., formed of glass)).

In forming the photodetector 10′, the layers 16, 18 are positioned opposite each other, and the nanowires 14, 14′, 14″ are grown from a surface of one of the layers 16, 18 until they attach/contact to a surface of the opposed layer 18, 16. Furthermore, nanowires 14, 14′, 14″ may be grown from one of the layers 16, 18 or from both of the layers 16, 18. Growth may be accomplished as previously described in reference to FIG. 1, with the addition of a third plurality of catalyst nanoparticles and a third precursor gas to initiate growth of the nanowires 14″.

FIGS. 3 and 4 depict still other embodiments of the photodetector 10″, 10′″. Referring specifically to FIG. 3, an embodiment of the photodetector 10″ includes one or more spaces S formed along the layers 16, 18 separating the plurality 12 of nanowires 14, 14′, 14″ into multiple sets 36, 38, 40. Such spaces S may be formed via selective positioning (e.g., using lithography) of the catalyst nanoparticles prior to nanowire 14, 14′, 14″ growth.

In an embodiment, the first set 36 includes nanowires 14 having a first bandgap, the second set 38 includes nanowires 14′ having a second bandgap (which is different from the first bandgap), and the third set 40 includes nanowires 14″ having a third bandgap (which is different from the first and second bandgaps). The first bandgap may be greater than the second bandgap, and the second bandgap may be greater than the third bandgap. In some instances, two or more sets 36, 38, 40 of nanowires 14, 14′, 14″ having the same bandgap may be included, as long as at least one other set 36, 38, 40 of nanowires 14, 14′, 14″ having a different bandgap is also included.

FIG. 3 also depicts contacts 30, 32 formed between the respective layers 16, 18 and the substrate 20. In some instances, the contact 30, 32 exhibits the same conductivity type (i.e., p-type or n-type) of the layer 16, 18 established thereon. It is to be understood that if the substrate 20 is an insulator, the contacts 30, 32 may be ohmic contacts, such as cobalt, molybdenum, titanium, chromium, nickel, palladium, or aluminum, doped with phosphorus, antimony, arsenic and/or boron. If the substrate 20 is a conductive material, an insulating layer (e.g., SiO₂) instead of a contact may be used to prevent shorting of the device 10″.

FIG. 4 illustrates an embodiment of the photodetector 10′″ in which sub-layers 16_{SL1}, 16_{SL2}, 16_{SL3}, 18_{SL1}, 18_{SL2}, 18_{SL3} of the layers 16, 18 are formed. The sublayers 16_{SL1}, 16_{SL2}, 16_{SL3}, 18_{SL1}, 18_{SL2}, 18_{SL3} are formed by establishing an insulating layer 34 to electrically isolate each of the sub-layers 16_{SL1}, 16_{SL2}, 16_{SL3}, 18_{SL1}, 18_{SL2}, 18_{SL3} within a respective layer 16, 18 from each of the other sub-layers 16_{SL1}, 16_{SL2}, 16_{SL3}, 18_{SL1}, 18_{SL2}, 18_{SL3} within a respective layer 16, 18. Non-limiting examples of suitable insulating layers 34 include glass, silicon dioxide, silicon nitride, aluminum oxide, or the like.

In forming such sub-layers 16_{SL1}, 16_{SL2}, 16_{SL3}, 18_{SL1}, 18_{SL2}, 18_{SL3}, it is to be understood that one sub-layer 16_{SL3}, 18_{SL3} may be established on the substrate 20, and then an insulating layer 34 may be established thereon. Another sub-layer 16_{SL2}, 18_{SL2} is then established on the insulating layer 34, and so on until a desirable number of sub-layers 16_{SL1}, 16_{SL2}, 16_{SL3}, 18_{SL1}, 18_{SL2}, 18_{SL3} and insulating layers 34 are formed. While three sub-layers 16_{SL1}, 16_{SL2}, 16_{SL3}, 18_{SL1}, 18_{SL2}, 18_{SL3} (separated by respective insulting layers 34) of each layer 16, 18 are shown in FIG. 4, it is to be understood that any desirable number of sub-layers 16_{SL1}, 16_{SL2}, 16_{SL3}, 18_{SL1}, 18_{SL2}, 18_{SL3} may be formed.

The insulating layer(s) 34 and sub-layers 16_{SL1}, 16_{SL2}, 16_{SL3}, 18_{SL1}, 18_{SL2}, 18_{SL3} may be established via any suitable technique, including, but not limited to sputter deposition (e.g., where different layers are deposited sequentially) or PECVD (e.g., where p-type or n-type microcrystalline or amorphous materials are deposited as sub-layers 16_{SL1}, 16_{SL2}, 16_{SL3}, 18_{SL1}, 18_{SL2}, 18_{SL3} and silicon nitride is used as an insulator 34). Photolithographic techniques or imprinting techniques may be used to define the sub-layers 16_{SL1}, 16_{SL2}, 16_{SL3}, 18_{SL1}, 18_{SL2}, 18_{SL3}. The sub-layers 16_{SL1}, 16_{SL2}, 16_{SL3}, 18_{SL1}, 18_{SL2}, 18_{SL3} may also be painted on using inkjet techniques followed by a subsequent thermal anneal.

When an insulating substrate 20 is selected, the sub-layer 16_{SL3}, 18_{SL3} may be established directly on the substrate 20. However, it is to be understood that when a conductive or semi-conductive substrate 20 is selected, another insulating layer 34′ is established between the substrate 20 and the first sub-layer 16_{SL3}, 18_{SL3} to substantially prevent electrical shorting.

Since the respective sub-layers 16_{SL1}, 16_{SL2}, 16_{SL3}, 18_{SL1}, 18_{SL2}, 18_{SL3} within the layers 16, 18 are electrically isolated from each of the other sub-layers 16_{SL1}, 16_{SL2}, 16_{SL3}, 18_{SL1}, 18_{SL2}, 18_{SL3}, each pair of sub-layers (e.g., 16_{SL1} and 18_{SL1}, 16_{SL2} and 18_{SL2}, or 16_{SL3} and 18_{SL3}) may be electrically addressed separately. As such, a contact 30, 32 is operatively connected to each of the sub-layers 16_{SL1}, 16_{SL2}, 16_{SL3}, 18_{SL1}, 18_{SL2}, 18_{SL3}.

The nanowires 14, 14′ 14″ in this embodiment of the device 10′″ have different bandgaps, however, the nanowires 14, 14′, 14″ may be grown such that all of the nanowires 14, 14′, 14″ extending from one particular sub-layer 16_{SL1}, 16_{SL2}, 16_{SL3} to another particular sub-layer 18_{SL1}, 18_{SL2}, 18_{SL3} have the same bandgap. For example, the nanowires 14 established between sub-layers 16_{SL1}, 18_{SL1} may have the largest bandgap (e.g., are formed of gallium nitride), the nanowires 14″ established between sub-layers 16_{SL3}, 18_{SL3} may have the smallest bandgap (e.g., are formed of indium nitride), while the nanowires 14′ established between sub-layers 16_{SL2}, 18_{SL2} may have a bandgap between the largest and smallest bandgaps (e.g., are formed of indium gallium nitride). As previously described, each of these nanowires 14, 14′, 14″ absorbs a different wavelength/range of wavelengths.

Furthermore, in the photodetector 10′″ shown in FIG. 4, the insulating layers 24 also provide spaces S between the respective nanowire sets 36, 38, 40.

Referring now to FIG. 5, an embodiment of a photovoltaic device 100 is depicted. The device 100 generally includes a layer 24 having a plurality of peaks P₁, P₂, P₃, P₄ and recesses R defined therein. The layer 24 may be established (and the peaks P₁, P₂, P₃, P₄ and recesses R defined) via any suitable deposition technique, including, but not limited to sputtering, evaporation, chemical vapor deposition, or the like. If the substrate 24 is pliable, the peaks P₁, P₂, P₃, P₄ and recesses R may be imprinted. Furthermore, the layer 24 may be formed of any suitable material, including, but not limited to a conducting material (e.g., metal), a semiconductor material (e.g., silicon), an insulator material (e.g. glass, SiO₂), or a polymeric material (e.g., Mylar®, available from DuPont, Wilmington Del.). It is to be understood that the layer 24 may function as a substrate, or may be established on another substrate 20 (non-limiting examples of which are previously described hereinabove).

On each peak P₁, P₂, P₃, P₄ of the layer 24, a doped material 26, 28 is established. The doped materials 26, 28 are generally formed of microcrystalline materials and/or amorphous material (e.g., microcrystalline silicon, microcrystalline germanium, alloys thereof, amorphous silicon, etc.) from which nanowires 14, 14′, 14″ may be grown. It is to be understood that the respective materials 26, 28 are doped with opposite conductivity types. For example, the first material 26 may be doped to have p-type or n-type conductivity, and the second material 28 may be doped to have the other of n-type or p-type conductivity.

As shown in FIG. 5, the respective materials 26, 28 are established on alternating peaks P₁, P₂, P₃, P₄, such that one peak P₁, P₃, is substantially covered with a p-type material or n-type material and an adjacent peak P₂, P₄ is substantially covered with the other of an n-type material or a p-type material. As a non-limiting example, the first material 26 is established on the first and third peaks P₁, P₃ and the second material 28 is established on the second and fourth peaks P₂, P₄. The doped materials 26, 28 may be established via any suitable technique (e.g., plasma enhanced chemical vapor deposition (PECVD)).

Between adjacent peaks P₁, P₂, P₃, P₄, a respective plurality 12, 12′, 12″ of nanowires 14, 14′, 14″ is formed. The peaks P₁, P₂, P₃, P₄ spatially separate the respective nanowires 14, 14′, 14″. In an embodiment, the nanowires 14 between one set of adjacent peaks P₁, P₂ have a bandgap that is different from a bandgap of the nanowires 14′, 14″ between each of the other sets of adjacent peaks P₂, P₃ and P₃, P₄. As such, in this embodiment, each of the pluralities 12, 12′, 12″ of nanowires 14, 14′, 14″ is capable of absorbing a different wavelength/range of wavelengths, thereby broadening the absorption spectrum of the device 100. In other embodiments, additional pluralities 12, 12′, 12″ of nanowires 14, 14′, 14″ having the same bandgap may be formed adjacent one another or at predetermined positions throughout the device 100. For example, nanowires 14 having a first bandgap may be formed between many sets of adjacent peaks (e.g., between P₁ and P₂ and between P₂ and P₃), and nanowires 14′ may be formed between another set of adjacent peaks (e.g., between peaks P₃ and P₄). In still another non-limiting example, the device 100 includes 40 peaks and the nanowires 14 (with a first bandgap) are formed between respective peaks of the first ten adjacent peaks in the device 100, nanowires 14′ (with a second bandgap) are formed between respective peaks of the next fifteen adjacent peaks in the device 100, and nanowires 14″ are formed between respective peaks of the final fifteen adjacent peaks in the device 100.

It is to be understood that the grouping of the pluralities 12, 12′, 12″ of nanowires 14, 14′, 14″ with different bandgaps will be determined, at least in part, by a grating or prism used to disperse or separate the light into different wavelengths spatially.

As a non-limiting example, the nanowires 14 may be formed of indium phosphide, the nanowires 14′ may be formed of indium antimonide, and the nanowires 14″ may be formed of silicon. It is to be understood that the nanowires 14, 14′, 14″ may also be formed of any of the other previously listed materials, as long as the bandgaps of the respective pluralities 12, 12′, 12″ of nanowires 14, 14′, 14″ are different.

The nanowires 14, 14′, 14″ may be grown as previously described using catalyst nanoparticles and different precursor gases that are suitable for obtaining the desirable different bandgaps. The pluralities 12, 12′, 12″ of nanowires 14, 14′, 14″ may be grown sequentially. For example, the catalyst nanoparticles on the areas of peaks P₁, P₂ that face each other may be selectively exposed to a first precursor gas to form nanowires 14, and then the catalyst nanoparticles on the areas of peaks P₂, P₃ that face each other may be selectively exposed to a second precursor gas to form nanowires 14′, and then the catalyst nanoparticles on the areas of peaks P₃, P₄ that face each other may be selectively exposed to a third precursor gas to form nanowires 14″.

As shown in FIG. 5, the nanowires 14, 14′, 14″ are substantially horizontally oriented (which, as previously described hereinabove includes randomly oriented nanowires) between the respective peaks P₁, P₂, P₃, P₄. At least some of the nanowires 14, 14′, 14″ may be grown from either doped material 26, 28 such that they extend from one surface horizontally or at any non-zero angle from the horizontal, and do not attach to the opposed doped material 28, 26. Some other of the nanowires 14, 14′, 14″ may be grown from one of the doped materials 26, 28 and attached to the opposed doped material 28, 26.

In the embodiment of FIG. 5, the device 100 includes multiple p-i-n and n-i-p structures, each of which includes the doped material 26, the nanowires 14, 14′, 14″ and the other doped material 28. Each structure is capable of converting light of a different wavelength/range of wavelengths into electricity. In use, light beams are directed into the device 100 through a prism or other dispersive element/diffractive optical element, which directs or partitions particular wavelengths/ranges of wavelengths to a particular plurality 12, 12′, 12″ of nanowires 14, 14′, 14″. Those light beams having a wavelength or range of wavelengths that correspond to a particular nanowire 14, 14′, 14″ are absorbed by the nanowires 14, 14′, 14″, and are subsequently converted into electricity.

Embodiments of the photodetector 10, 10′, 10″, 10′″ and device 100 disclosed herein offer many advantages, and may suitable be used for a number of applications. If desirable, the photodetector 10, 10′, 10″, 10′″ and device 100 may be manufactured without single crystalline layers, which is believed to reduce the cost of manufacturing.

While several embodiments have been described in detail, it will be apparent to those skilled in the art that the disclosed embodiments may be modified. Therefore, the foregoing description is to be considered exemplary rather than limiting.

What is claimed is:

1. A photodetector, comprising:
a first layer;
a second layer; and
a plurality of nanowires established between the first and second layers, at least some of the plurality of nanowires having a bandgap that is different from a bandgap of at least some other of the plurality of nanowires.

2. The photodetector as defined in claim 1 wherein the first layer is doped to have one of n-type or p-type conductivity, and wherein the second layer is doped to have an other of p-type or n-type conductivity.

3. The photodetector as defined in claim 1 wherein at least one of the first layer or the second layer is selected from amorphous materials, polycrystalline materials, and single crystalline materials.

4. The photodetector as defined in claim 1 wherein the at least some of the plurality of nanowires are formed of a first semiconductor material, wherein the at least some other of the plurality of nanowires are formed of a second semiconductor material, and wherein the first and second semiconductor materials are different.

5. The photodetector as defined in claim 4 wherein the first and second semiconductor materials are selected from silicon, germanium, indium phosphide, gallium arsenide, gallium nitride, indium antimonide, indium nitride, indium gallium nitride, or combinations thereof.

6. The photodetector as defined in claim 1 wherein the plurality of nanowires is established substantially vertically or substantially horizontally between the first and second layers.

7. The photodetector as defined in claim 6 wherein the plurality of nanowires is established substantially horizontally between the first and second layers, and wherein nanowires located adjacent a top of the device absorb shorter wavelengths than nanowires located adjacent a bottom of the device.

8. The photodetector as defined in claim 6 wherein the plurality of nanowires is established substantially horizontally between the first and second layers, and wherein the photodetector further comprises:
a first contact upon which the first layer is established, the first contact having a first conductivity type;
a second contact upon which the second layer is established, the second contact having a second conductivity type that is different from the first conductivity type; and
a substrate upon which the first and second contacts are established.

9. The photodetector as defined in claim 1 wherein each of the first and second layers is divided into at least two sub-layers by an insulating layer, and wherein the at least some of the plurality of nanowires extend between a first sub-layer of the first layer and a first sub-layer of the second layer, and wherein the at least some other of the plurality of nanowires extend between a second sub-layer of the first layer and a second sub-layer of the second layer.

10. The photodetector as defined in claim 1 wherein the at least some of the plurality of nanowires are separated from the at least some other of the plurality of nanowires via a space.

11. The photodetector as defined in claim 1 wherein the at least some of the plurality of nanowires are intermingled with the at least some other of the plurality of nanowires.

12. The photodetector as defined in claim 1 wherein each of the at least some of the plurality of nanowires has a first diameter, and wherein each of the at least some other of the plurality of nanowires has a second diameter that is different from the first diameter.

13. A method of making a photodetector, the method comprising:
growing a plurality of nanowires from at least one of a first layer or a second layer such that at least some of the plurality of nanowires have a bandgap that is different from a bandgap of at least some other of the plurality of nanowires; and
contacting the plurality of nanowires to at least an other of the second layer or the first layer.

14. The method as defined in claim 13 wherein growing is accomplished by:
establishing a first plurality of catalyst nanoparticles on the at least one of the first layer or the second layer;
exposing the first plurality of catalyst nanoparticles to a first precursor gas, thereby initiating growth of the at least some of the plurality of nanowires;
establishing a second plurality of catalyst nanoparticles on the at least one of the first layer or the second layer; and
exposing the second plurality of catalyst nanoparticles to a second precursor gas that is different from the first precursor gas, thereby initiating growth of the at least some other of the plurality of nanowires.

15. The method as defined in claim 14 wherein exposing is accomplished by metal organic chemical vapor deposition (MOCVD), gas source molecular beam epitaxy (MBE), hydride vapor phase epitaxy (HVPE), or chloride vapor phase epitaxy (Cl-VPE).

16. The method as defined in claim 13 wherein the plurality of nanowires is established substantially vertically between the first and second layers, and wherein contacting the plurality of nanowires to the at least the other of the second layer or the first layer includes:
forming an additional layer on the at least one of the first layer or the second layer such that the additional layer surrounds each nanowire in the plurality of nanowires;
planarizing the additional layer having the plurality of nanowires therein; and
establishing the at least the other of the second layer or the first layer on the planarized additional layer having the plurality of nanowires therein.

17. The method as defined in claim 13 wherein the plurality of nanowires is established substantially horizontally between the first and second layers, and wherein contacting the plurality of nanowires to the at least the other of the second layer or the first layer includes:
positioning the at least the other of the second layer or the first layer opposed to a surface of the at least one of the first layer or the second layer from which the plurality of nanowires is grown; and
growing the plurality of nanowires until the plurality of nanowires contacts the at least the other of the second layer or the first layer.

18. The method as defined in claim 13, further comprising:
incorporating at least one insulating layer into each of the first and second layers, thereby dividing each of the first and second layers into at least two sub-layers;
growing the at least some of the plurality of nanowires such that they extend between a first sub-layer of the first layer and a first sub-layer of the second layer; and
growing the at least some other of the plurality of nanowires such that they extend between a second sub-layer of the first layer and a second sub-layer of the second layer.

19. The method as defined in claim 13 wherein growing is accomplished by:
establishing a first plurality of catalyst nanoparticles on the at least one of the first layer or the second layer, the first plurality of catalyst nanoparticles having a size suitable for growing the at least some of the plurality of nanowires having a first diameter;
exposing the first plurality of catalyst nanoparticles to a precursor gas, thereby initiating growth of the at least some of the plurality of nanowires;
establishing a second plurality of catalyst nanoparticles on the at least one of the first layer or the second layer, the second plurality of catalyst nanoparticles having a size suitable for growing the at least some other of the plurality of nanowires having a second diameter that is different from the first diameter; and
exposing the second plurality of catalyst nanoparticles to a second precursor gas that is different from the first precursor gas, thereby initiating growth of the at least some other of the plurality of nanowires.

20. A photovoltaic device, comprising:
a layer having a plurality of alternating peaks and recesses defined therein;
a material doped with a first conductivity type and a second material doped with a second conductivity type, respectively established on alternating peaks in the plurality of peaks;
a first plurality of nanowires established between a first and a second of the plurality of peaks, the first plurality of nanowires formed of a first semiconductor material; and
a second plurality of nanowires established between the second and a third of the plurality of peaks, wherein the second plurality of nanowires is formed of a second semiconductor material having a bandgap that is different from a bandgap of the first semiconductor material.

21. The photovoltaic device as defined in claim 20 wherein i) at least some of the first plurality of nanowires are grown from the first of the plurality of peaks and at least some other of the first plurality of nanowires are grown from the second of the plurality of peaks, ii) at least some of the second plurality of nanowires are grown from the second of the plurality of peaks and wherein at least some other of the second plurality of nanowires are grown from the third of the plurality of peaks, or iii) combinations of i and ii.

22. The photovoltaic device as defined in claim 20, further comprising a third plurality of nanowires established between the third and a fourth of the plurality of peaks, wherein the third plurality of nanowires is formed of a third semiconductor material having a bandgap that is different from the bandgap of the first semiconductor material and the bandgap of the second semiconductor material.

23. A method of making a photovoltaic device, the method comprising:
respectively establishing a first material doped with a first conductivity type and a second material doped with a second conductivity type on alternating peaks of a plurality of peaks defined in a layer;
growing a first plurality of nanowires substantially horizontally between a first and a second of the plurality of peaks, the first plurality of nanowires formed of a first semiconductor material; and
growing a second plurality of nanowires substantially horizontally between the second and a third of the plurality of peaks, wherein the second plurality of nanowires is formed of a second semiconductor material having a bandgap that is different from a bandgap of the first semiconductor material.

24. The method as defined in claim 23 wherein the first material doped with the first conductivity type is established on the first and third peaks, wherein the second material doped with the second conductivity type is established on the second peak, and wherein growing the first and second pluralities of nanowires is accomplished by:
sequentially establishing a plurality of catalyst nanoparticles on i) at least one of the first material established on the first peak or the second material established on the second peak, and ii) at least one of the second material established on the second peak or the first material established on the third peak;
selectively exposing the plurality of catalyst nanoparticles on the at least one of the first material established on the first peak or the second material established on the second peak to a first precursor gas; and
selectively exposing the plurality of catalyst nanoparticles the on at least one of the second material established on the second peak or the first material established on the third peak to a second precursor gas that is different from the first precursor gas.

25. The method as defined in claim 23, further comprising growing a third plurality of nanowires substantially horizontally between the third and a fourth of the plurality of peaks, wherein the third plurality of nanowires is formed of a third semiconductor material having a bandgap that is different from the bandgap of the first semiconductor material and the bandgap of the second semiconductor material.
